(19) United States
(12) Patent Application Publication
(10) Pub. No.: US 2026/0180238 A1
(43) Pub. Date: Jun. 25, 2026

(54) CONNECTOR SEALING INTERFACES FOR ELECTRONIC CONTROL UNITS

(71) Applicant: Cummins Inc., Columbus, IN (US)

(72) Inventors: Mahesh Anandrao Jamdade, Pune (IN); John Borneman, Morgantown, IN (US)

(21) Appl. No.: 18/987,364

(22) Filed: Dec. 19, 2024

(51) Int. Cl. H01R 13/52; H01R 13/66; H05K 5/00; H05K 5/10

(52) U.S. Cl. CPC H01R 13/5202; H01R 13/5216; H01R 13/665; H05K 5/0052; H05K 5/10

(57) ABSTRACT

A connector sealing interface between an enclosure and electrical connector in an electronic control unit is provided. The electronic control unit includes a housing including a cover plate and an enclosure coupled with the cover plate. The enclosure includes a connector opening and a fastener opening spaced apart from the connector opening. The electrical control unit also includes an electrical connector operatively coupled with a PCB and extending through the connector opening and a fastener extending through the fastener opening and extending into and engaging a fastener receptacle of the electrical connector to fasten the electrical connector to the enclosure. The electrical connector further includes a sealing interface formed between the enclosure and the electrical connector which includes a pedestal protruding from an interior surface of the enclosure, a receiving groove formed in the electrical connector receiving a portion of the pedestal, and a sealant bead disposed intermediate and contacting the pedestal and the receiving groove to form a seal.

### TECHNICAL FIELD

The present application relates generally to electronic control units, and more particularly, to connector sealing interfaces for electronic control units.

### BACKGROUND

Plastic enclosures are used to save cost for electronic control units. However, when plastic enclosures are assembled to electrical connectors (e.g., bottom mounted electrical connectors), seal immersion test criteria become difficult to meet. Current sealing designs with, for example, a rubber gasket in the electrical connector are inadequate to meet seal immersion tests. As well, current enclosure designs are inadequate to compress the rubber gasket to meet sealing requirements. To meet sealing requirements, rubber gaskets have been replaced by dispensing a sealant into a cavity formed in the electrical connector. However, when the enclosure interfaces with the connector cavity, a gap between the enclosure and connector cavity causes the sealant to not fully cure. Additionally, current designs cause a bending deformation of the enclosure during the fastening and sealing of the enclosure and electrical connector. There remains a significant need for the unique solutions disclosed herein to address these issues among others.

### DISCLOSURE OF EXAMPLE EMBODIMENTS

For the purposes of clearly, concisely, and exactly describing example embodiments of the present disclosure, the manner, and process of making and using the same, and to enable the practice, making and use of the same, reference will now be made to certain example embodiments, including those illustrated in the figures, and specific language will be used to describe the same. It shall nevertheless be understood that no limitation of the scope of the invention is thereby created, and that the invention includes and protects such alterations, modifications, and further applications of the example embodiments as would occur to one skilled in the art.

### SUMMARY

The present disclosure includes a connector sealing interface for an electronic control unit. In one embodiment, the electronic control unit includes a housing including a cover plate and an enclosure coupled with the cover plate, the enclosure including a connector opening and a fastener opening spaced apart from the connector opening. The electronic control unit includes a printer circuit board (PCB) contained within the housing intermediate the cover plate and the enclosure, and an electrical connector operatively coupled with the PCB and extending through the connector opening to an exterior of the housing and including a fastener receptacle. The electronic control unit further includes a fastener extending through the fastener opening and extending into and engaging the fastener receptacle to fasten the electrical connector to the enclosure, and a sealing interface formed between an interior surface of the enclosure and the electrical connector. The sealing interface includes a pedestal protruding from the interior surface of the enclosure, a receiving groove formed in the electrical connector and receiving at least a portion of the pedestal, and a sealant bead disposed intermediate and contacting the pedestal and the receiving groove to form a seal.

In another embodiment, a process includes providing unassembled electronic control unit components. The unassembled electronic control unit components includes a housing including a cover plate and an enclosure coupled with the cover plate, the enclosure including a connector opening and a fastener opening spaced apart from the connector opening. The unassembled electronic control unit components further includes a PCB contained within the housing intermediate the cover plate and the enclosure, an electrical connector operatively coupled with the PCB and extending through the connector opening to an exterior of the housing and including a fastener receptacle, a fastener extending through the fastener opening and extending into and engaging the fastener receptacle to fasten the electrical connector to the enclosure, and a sealing interface formed between an interior surface of the enclosure and the electrical connector. The process further includes assembling the unassembled electronic control unit components, the assembling including mounting the electrical connector onto the PCB, dispensing a sealant bead into a receiving groove formed in the electrical connector, and inserting the electrical connector through the connector opening of the enclosure. The assembling further includes receiving a pedestal protruding from the interior surface of the enclosure into the receiving groove, contacting the pedestal to the sealant bead in the receiving groove, and fastening the enclosure to the electrical connector, wherein the sealant bead is disposed intermediate and contacts the pedestal and the receiving groove to form a seal.

This summary is not intended to identify key or essential features of the claimed subject matter, nor is it intended to be used as an aid in limiting the scope of the claimed subject matter. Further embodiments, forms, objects, features, advantages, aspects, and benefits shall become apparent from the following description and drawings.

### BRIEF DESCRIPTION OF THE DRAWINGS

The description herein makes reference to the accompanying drawings wherein like numerals refer to like parts throughout the several views, and wherein:

FIG. 1 is a perspective view of an electronic control unit including an enclosure and electronic connector, according to an example embodiment.

FIG. 2 is an exploded perspective view of the electronic control unit in FIG. 1, according to an example embodiment.

FIG. 3 is a perspective view of an interior of the enclosure with a pedestal protruding from the interior surface, according to an example embodiment.

FIG. 4 is a perspective view of the electrical connector with a receiving groove for the pedestal, according to an example embodiment.

FIG. 5 is a perspective view of the electronic control unit with the pedestal positioned in the receiving groove of the electrical connector, according to an example embodiment.

FIG. 6 is a detailed view of the pedestal positioned in the receiving groove of the electrical connector, according to an example embodiment.

FIG. 7 is a schematic view of the electronic control unit with the pedestal positioned in the receiving groove of the electrical connector, according to an example embodiment.

FIG. 8 is a detailed view of the pedestal positioned in the receiving groove of the electrical connector, according to an example embodiment.

FIG. 9 is a flow diagram illustration of an example procedure for assembling the electronic control unit components, according to an example embodiment.

FIG. 10 is a schematic view depicting certain aspects of an example system.

### DETAILED DESCRIPTION OF EXAMPLE EMBODIMENTS

Some example embodiments relate to an electronic control unit (ECU) having a connector sealing interface between an enclosure and bottom mounted connector of the ECU. The ECU may have a housing that includes the enclosure, a cover plate, and a PCB contained within the housing intermediate the enclosure and cover plate. In an example embodiment, the ECU may include an electrical connector such as, for example, a bottom mounted connector, coupled to the PCB and configured to protrude through a connector opening provided in the enclosure. The connector opening may protrude or extend through the enclosure to an exterior of the housing. In an example embodiment, the ECU may include a sealing interface between the enclosure and the electrical connector. For example, the sealing interface may be formed by a pedestal protruding from an interior surface of the enclosure interfacing with a receiving groove formed in the electrical connector. In an example embodiment, the sealing interface may include a sealant bead disposed intermediate and contacting the pedestal and the receiving groove of the electrical connector to form a seal.

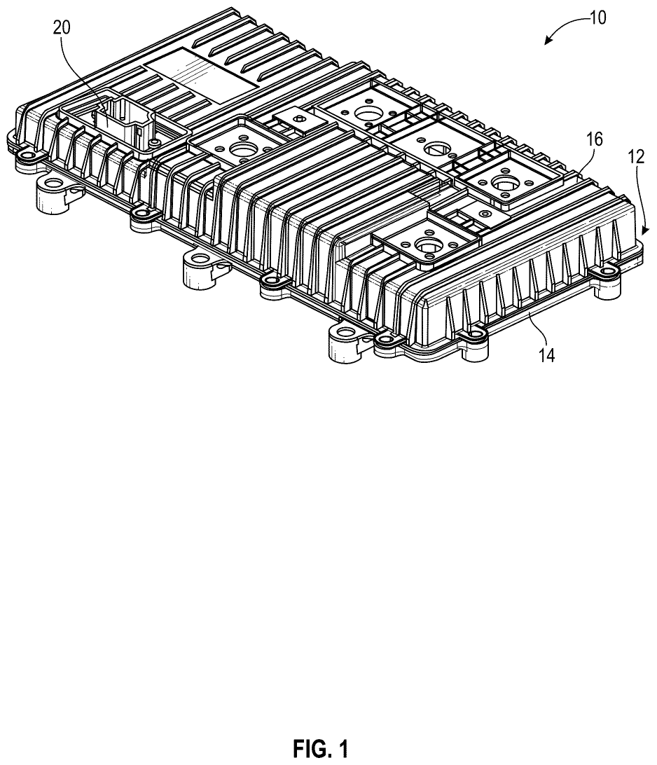

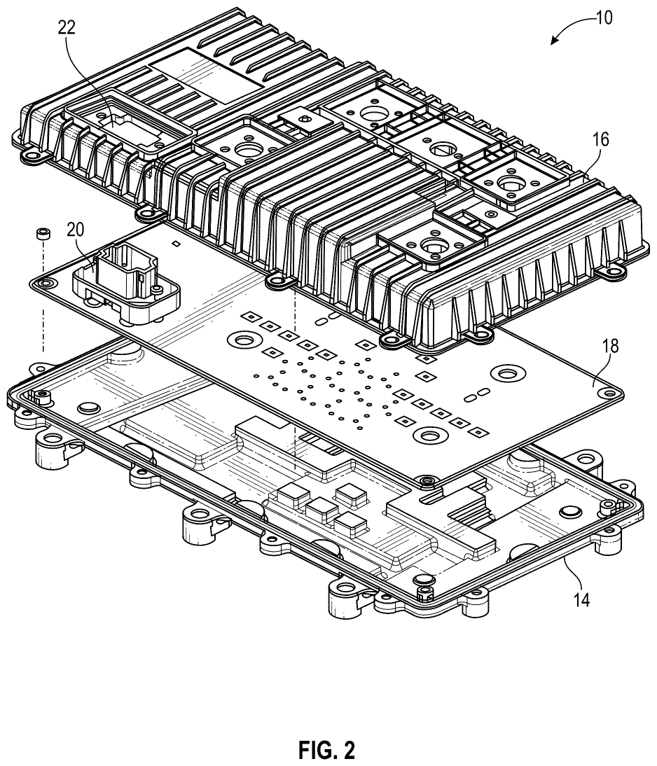

With reference to FIGS. 1 and 2, there is illustrated an example electronic control unit (ECU) 10 includes a housing 12 having a cover plate 14 and an enclosure 16 coupled to the cover plate 14. In the illustrated example, housing 12 is configured and provided in the form of a plastic enclosure including a plurality of generally rectangular wall structures bounding an interior space which is adapted to receive electronic components contained within ECU and cover plate 14 is configured and provided in the form generally rectangular wall structure that can be selectably attached to and removed from housing 12 to form a generally box-shaped structure that encloses and seal electronics within ECU 10 from exposure to potentially deleterious elements such as air, fluids, moisture, particles, and other contaminants. Other embodiments may comprise housings and cover plates having differing geometries, shapes and sizes, as well occur to one of skill in the art with the benefit and insight of the present disclosure.

A printed circuit board (PCB) 18 is provided within the housing 12 intermediate the cover plate 14 and the enclosure 16. The PCB 18 includes one or more electrical connectors mounted thereon such as, for example, top and bottom mounted connectors. In the example embodiment, an electrical connector 20 (e.g., bottom mounted connector) may be operatively coupled with the PCB 18. The enclosure 16 includes a connector opening 22 that receives the electrical connector 20 such that electrical connector 20 extends to an exterior of the housing 12 when ECU 10 is assembled. The PCB 18 further includes electronic components mounted thereon such as microcontrollers, integrated circuit devices, and discrete components such as resistors, capacitors, and inductors, among other circuitry and components.

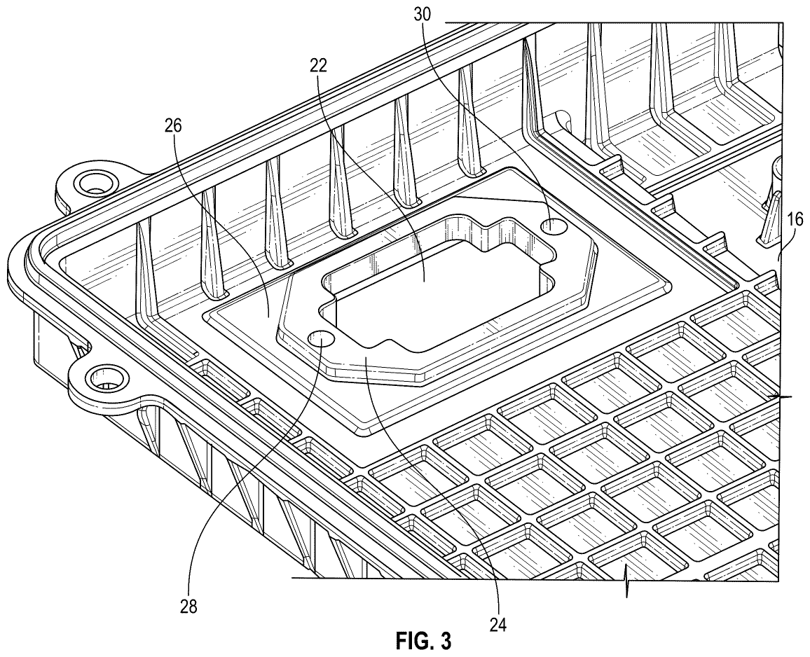

With reference to FIG. 3, the enclosure 16 includes a pedestal 24 protruding from at least a portion of an interior surface 26 of the enclosure 16 that interfaces with the electrical connector 20. In the example embodiment, the pedestal 24 may comprise an octagonal shape but other shapes are contemplated to interface with the electrical connector 20. The connector opening 22 may be provided inside the pedestal 24 such that the pedestal 24 surrounds a perimeter of the connector opening 22. Additionally, the enclosure 16 includes a fastener opening 26 proximate and spaced apart from the connector opening 22. The fastener opening 28 may be configured to extend through a portion of the pedestal 24. In some embodiments, the enclosure 16 includes a second fastener opening 30 proximate and spaced apart from the connector opening 22. For example, the second fastener opening 30 may be configured to extend through a portion of the pedestal 24 at an opposite side of the connector opening 22 from the fastener opening 28. While the enclosure 16 shows fastener opening 28 and second fastener opening 30, it shall be appreciated by persons skilled in the art that additional fastener openings may be provided in the enclosure 16 to protrude through pedestal 24 to fasten an electrical connector to the enclosure 16.

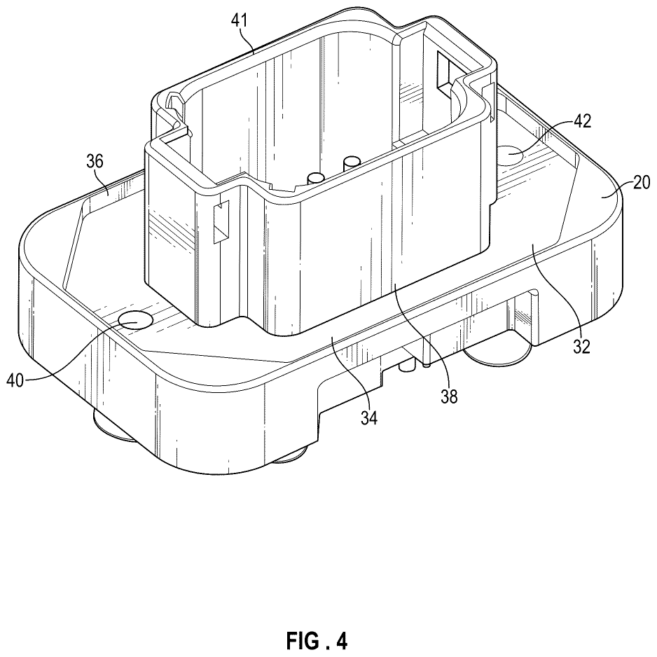

With reference to FIG. 4, a receiving groove 32 may be formed in the electrical connector 20 to receive at least a portion of the pedestal 24. In the example embodiment, the receiving groove 32 includes a bottom surface 34, an outer side surface 36, and an inner side surface 38. Additionally, the electrical connector 20 includes a fastener receptacle 40 formed in the receiving groove 32 and extending through a portion of the electrical connector 20. The fastener receptacle 40 may be proximate and spaced apart from a protruding portion 41 of the electrical connector 20 that extends through the connector opening 22 to the exterior of the housing 12. The fastener receptable 40 may be configured to share a common axis with the fastener opening 28 of the enclosure 16. In some embodiments, the electrical connector 20 includes a second fastener receptacle 42 formed in the receiving groove 32 proximate and spaced apart from the protruding portion 41. The second fastener receptacle 42 may be configured to extend through a portion of the electrical connector 20 at an opposite side of the protruding portion 41 from the fastener receptable 40. The second fastener receptacle 42 may be configured to share a common axis with the second fastener opening 30. While the electrical connector 20 shows fastener receptacle 40 and second fastener receptacle 42, it shall be appreciated by persons skilled in the art that additional fastener receptables may be contemplated to accommodate fastener openings in the enclosure 16.

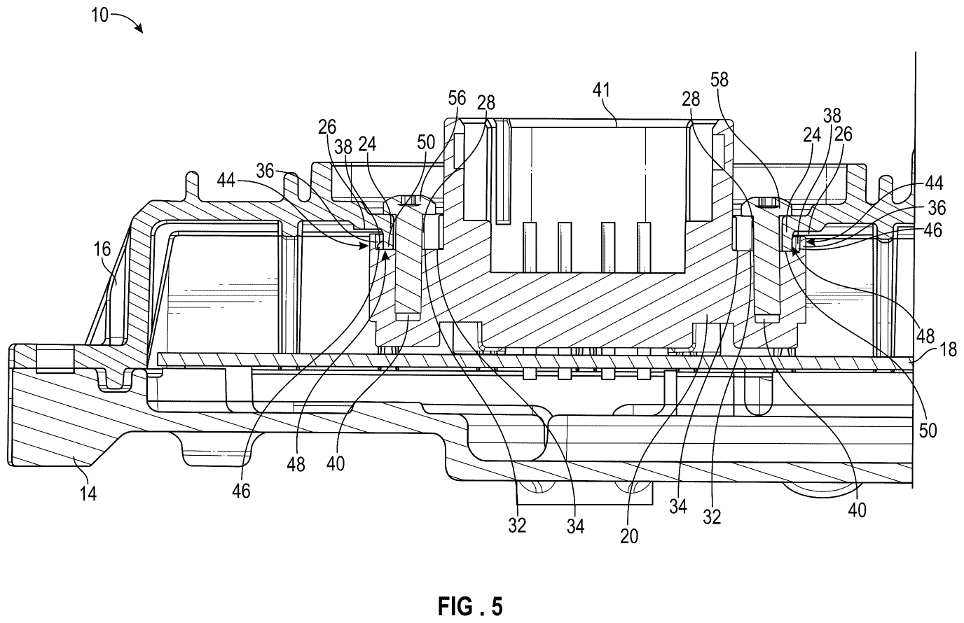

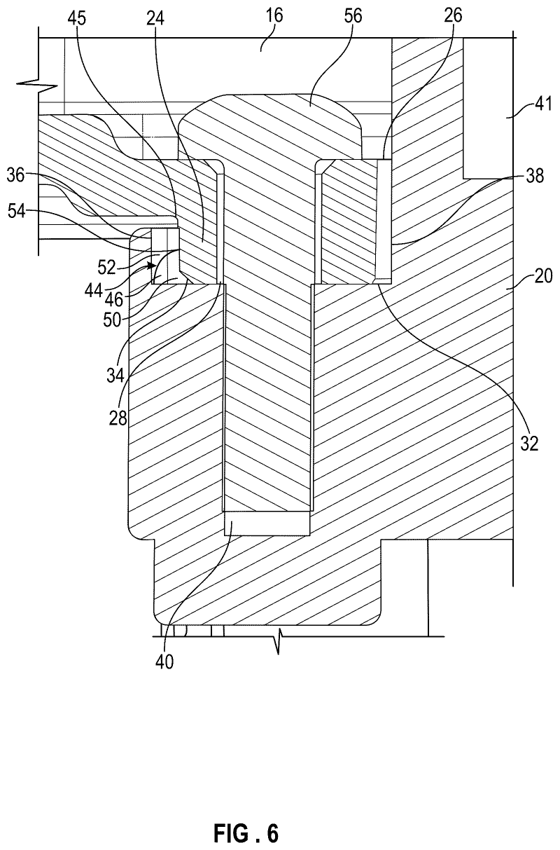

With reference to FIGS. 5 and 6, a sealing interface 44 may be formed between the interior surface 26 of the enclosure 16 and the electrical connector 20. In the example embodiment, the sealing interface 44 includes the pedestal 24 protruding from the interior surface 26 and received in the receiving groove 32. For example, a radius transition 45 may be formed where the pedestal 24 extends from the interior surface 26 towards the receiving groove 32.

The sealing interface 44 may also include a sealant bead 46 disposed intermediate the pedestal 24 and the receiving groove 32. The sealant bead 46 contacts the pedestal 24 and the receiving groove 32 to form a seal. In the example embodiment, the sealant bead 46 may be an adhesive type sealant, however, other types of sealants may be contemplated.

According to an example embodiment, an outer perimeter 48 of the pedestal 24 may be configured with a chamfer 50. The chamfer 50 may be provided at the sealing interface 44 at a location adjacent to and where the pedestal 24 and the receiving groove 32 abut. Additionally, a gap 52 may be provided at an outer side surface 54 of the pedestal 24 and an outer side surface of the receiving groove 32. For example, the gap 52 may be formed when the enclosure 16 fastens to the electrical connector 20. A portion of the sealant bead 46 may be positioned in the gap 52. A fastener 56 may be provided to extend through the fastener opening 28 and into the fastener receptacle 40 to fasten the electrical connector 20 to the enclosure 16. At an opposite side of the electrical connector 20 from the fastener opening 28 and the fastener receptacle 40, a second fastener 58 may be provided to extend through the second fastener opening 30 and into the fastener receptacle 42 to fasten the electrical connector 20 to the enclosure 16.

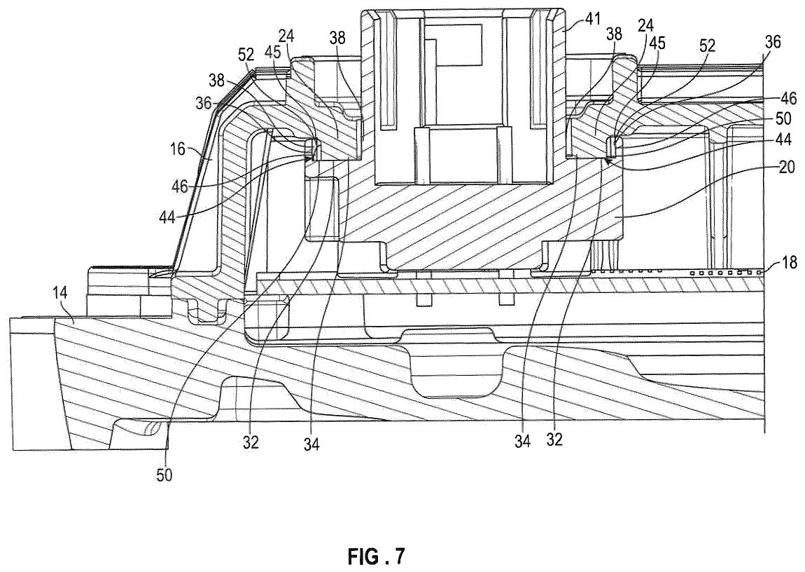

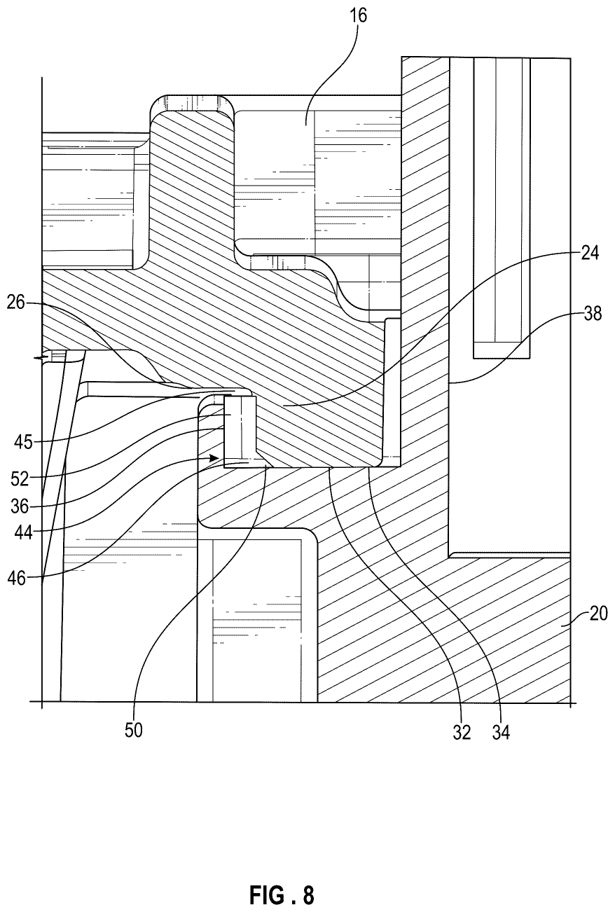

With reference to FIGS. 7 and 8, a perspective view of the sealing interface 44 between the pedestal 24 positioned in the receiving groove 32 of the electrical connector 20 is shown without the fastener 56 and second fastener 58. In FIGS. 7 and 8, the pedestal 24 is shown protruding from the interior surface 26 and received in the receiving groove 32.

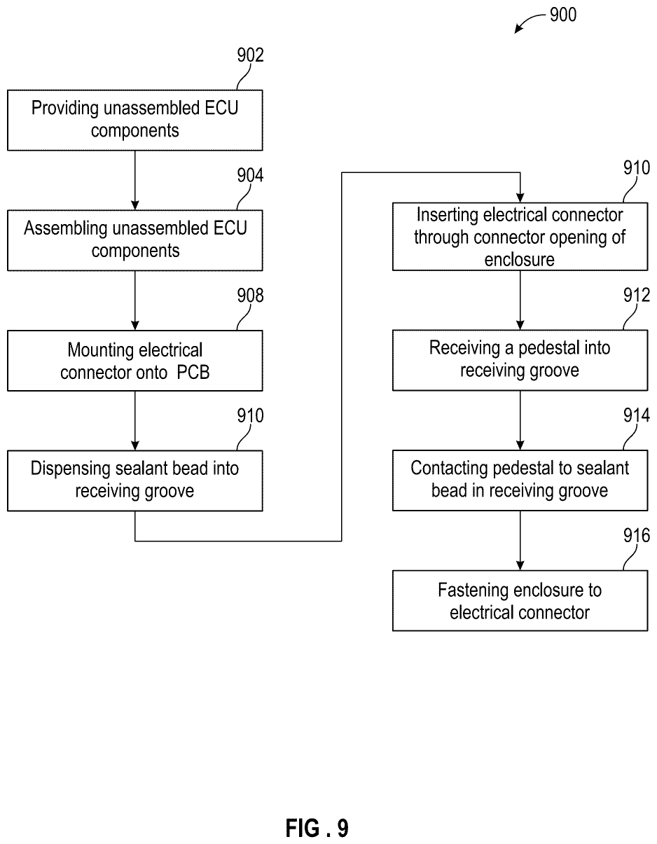

With reference to FIG. 9, there is illustrated a flow diagram of an example procedure 900 for assembling ECU 10 components according to an example embodiment of the present disclosure. Procedure 900 begins at operation 902 which provides the unassembled ECU 10 components that includes a housing 12 including a cover plate 14 and an enclosure 16 coupled with the cover plate 14. The enclosure 16 includes a connector opening 22 and a fastener opening 28 spaced apart from the connector opening 22. The ECU 10 includes PCB 18 contained within the housing 12 intermediate the cover plate 14 and the enclosure 16. The ECU 10 includes an electrical connector 20 operatively coupled with the PCB 18 and extending through the connector opening 22 to an exterior of the housing 12 and including a fastener receptacle 40. The ECU 10 includes a fastener 56 extending through the fastener opening 28 and extending into and engaging the fastener receptacle 40 to fasten the electrical connector 20 to the enclosure 16. Additionally, the ECU 10 includes a sealing interface 44 formed between an interior surface 26 of the enclosure 16 and the electrical connector 20. From operation 902, procedure 900 continues to operation 904 which assembles the unassembled ECU 10 components described in operation 902.

From operation 904, procedure continues to operation 906 which mounts the electrical connector 20 onto the PCB 18. From operation 906, procedure 900 continues to operation 908 which dispenses a sealant bead 46 into a receiving groove 32 formed in the electrical connector 20. From operation 908, procedure 900 continues to operation 910 which inserts the electrical connector 20 through the connector opening 22 of the enclosure 16. From operation 910, procedure 900 continues to operation 912 which receives a pedestal 24 protruding from the interior surface 26 of the enclosure 16 into the receiving groove 32. From operation 912, procedure 900 continues to operation 914 which contacts the pedestal 24 to the sealant bead 46 in the receiving groove 32. From operation 914, procedure 900 continues to operation 916 which fastens the enclosure 16 to the electrical connector 20. According to example embodiment, the sealant bead 46 may be disposed intermediate and contacts the pedestal 24 and the receiving groove 32 to form a seal. It shall be appreciated that after completion of assembling operation 916, a leak test or seal pressure test such as air pressure or leak test or a water or other fluid pressure or leak test may be performed.

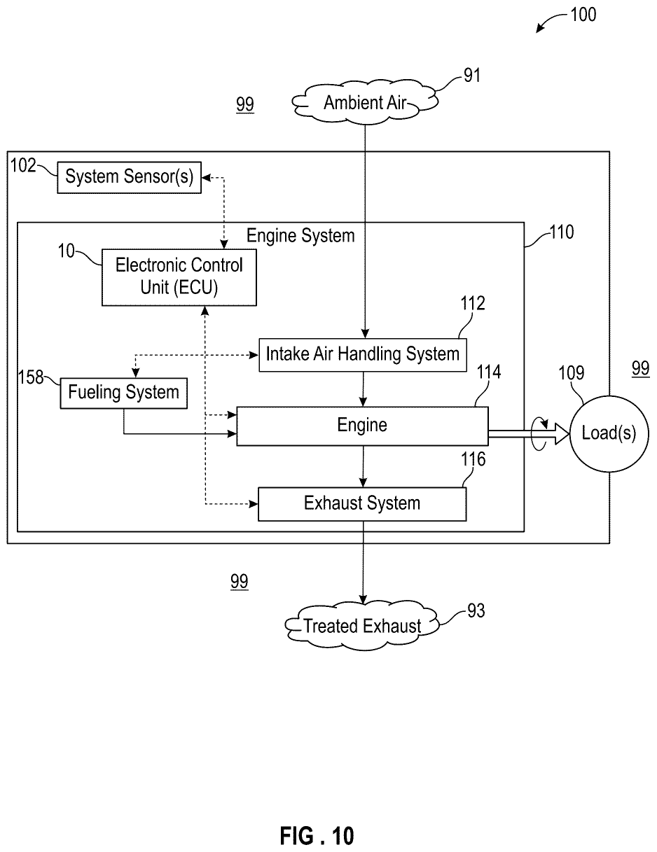

With reference to FIG. 10, there is illustrated an example system 100 including a prime mover system 110 (also referred to herein as system 110) and at least a portion of one or more loads 109. System 100 may be provide in a number of forms including, for example, in the form of a vehicle or vehicle powertrain system (e.g., an on-highway vehicle or vehicle powertrain system or an off-highway vehicle or vehicle powertrain system), a work machine or work machine powertrain system, a genset or genset powertrain system, or a hydraulic fracturing rig or hydraulic fracturing rig powertrain system, to name several non-limiting examples. In shall be appreciated that system 100 may include a number of other components as will occur to one of skill in the art with the benefit and insight of the present disclosure.

In the illustrated example, system 110 is configured and provided as an internal combustion engine system including an intake air handling system 112, an engine 114, an exhaust system 116, a fueling system 158, and an electronic control system 130. It shall be appreciated that system 110 may include a number of other components as will occur to one of skill in the art with the benefit and insight of the present disclosure. In other example embodiments, system 110 may be configured and provided as another type of prime mover system such as, for example, a hybrid combustion engine-electric prime mover system, a battery electric prime mover system, a fuel cell prime mover system, or another type of prime mover system.

Intake air handling system 112 may include one or more air handling conduits, air filters, compressors (such as a compressor of a turbocharger or supercharger), coolers (such as charger air coolers, intercoolers, and/or aftercoolers which may be, for example, of an air-to-air type or an air-to-liquid type), and sensors (such as temperature sensors, pressure sensors, mass flow sensors, and other types of sensors), as well as other components.

Engine 114 may be provided in a number of forms and typically includes a block including a plurality of cylinders and a head coupled with the block. The head typically includes intake ports, intake valves configured to selectively open and close the intake ports, exhaust ports, exhaust valves configured to selectively open and close the exhaust ports, injector bores, fuel injectors disposed in the injector bores, spark plug bores, and spark plugs disposed in the spark plug bores. A plurality of pistons may be provided in respective ones of the plurality of cylinders. A crankshaft may be coupled with the plurality of pistons and configured to translate reciprocating motion of the plurality of pistons to provide torque for driving loads 109 which may include internal loads of system 110 (such oil pumps, valvetrains, fuel pumps and other loads of engine 114, and accessory loads of system 110). It shall be appreciated that system 110 may include a number of other components as will occur to one of skill in the art with the benefit and insight of the present disclosure.

Exhaust system 116 may include one or more exhaust handling conduits, turbines (such as a turbine of a turbocharger), aftertreatment components (such as oxidation catalysts, particular filters, selective catalytic reduction (SCR) catalysts, and/or other catalysts and aftertreatment components), and sensors (such as temperature sensors, pressure sensors, oxygen or lambda sensors, mass flow sensors, and other types of sensors), as well as other components.

Fueling system 158 may be configured and provided as a high-pressure common-rail fuel injection system including a plurality of fuel injectors in fluid communication with a common fuel rail, which supplies fuel at relatively high pressure to the plurality of fuel injectors. Fuel may be supplied to the common fuel rail by a high-pressure pump which, in turn, may be fed by a relatively low-pressure fuel circuit including a booster pump, which may be immersed in a tank containing a reservoir of fuel.

ECS 130 preferably includes one or more electronic control units such as ECU 10 or another electronic control unit according to the present disclosure. The one or more electronic control units preferably include one or more programmable microcontrollers of a solid-state, integrated circuit type, and one or more non-transitory memory media configured to store instructions executable by the one or more microcontrollers. For purposes of the present application the term microcontroller shall be understood to also encompass microprocessors and other types of integrated circuit processors. ECS 130 is in operative communication with and may be adapted and configured to control operation of and/or receive inputs from sensors or controllers of intake air handling system 112, engine 114, exhaust system 116, and fueling system 158. ECS 130 is in operative communication with and may be adapted and configured to control operation of and/or receive inputs from one or more system sensors 102 of system 100 which may include, for example, a throttle position sensor or an accelerator position sensor. It shall be appreciated that FIG. 1 depicts control relationships between the foregoing components conceptually using dashed arrows and that various communications hardware and protocols may be utilized to implement, such as one or more controller area networks (CAN) or other communications components.

ECS 130 can be implemented in any of a number of ways that combine or distribute the control function across one or more control units in various manners. The ECS 130 may execute operating logic that defines various control, management, and/or regulation functions. This operating logic may be in the form of dedicated hardware, such as a hardwired state machine, analog calculating machine, programming instructions, and/or a different form as would occur to those skilled in the art. The ECS 130 may be provided as a single component or a collection of operatively coupled components; and may be comprised of digital circuitry, analog circuitry, or a hybrid combination of both of these types. When of a multi-component form, the ECS 130 may have one or more components remotely located relative to the others in a distributed arrangement. The ECS 130 can include multiple processing units arranged to operate independently, in a pipeline processing arrangement, in a parallel processing arrangement, or the like. It shall be further appreciated that the ECS 130 and/or any of its constituent components may include one or more signal conditioners, modulators, demodulators, Arithmetic Logic Units (ALUs), Central Processing Units (CPUs), limiters, oscillators, control clocks, amplifiers, signal conditioners, filters, format converters, communication ports, clamps, delay devices, memory devices, Analog to Digital (A/D) converters, Digital to Analog (D/A) converters, and/or different circuitry or components as would occur to those skilled in the art to perform the desired communications.

An operating environment 99 is also depicted in FIG. 10. As described above, during typical operation of system 100, ambient air 91 of operating environment 99 is received as an input to system 100, and treated exhaust 93 from system 100 is released to operating environment 99. In some embodiments, loads 109 may at least in part comprise a portion of operating environment 99. For example, in embodiments where system 100 is provided in the form of a genset or genset powertrain system, the one or more loads 109 may comprise loads at various nodes in a distributed power network in addition to load components which, even if small, are integral to system 100. As another example, in embodiments where system 100 is provided in the form of a vehicle or vehicle powertrain system, loads 109 may include forces such as wind, gravity, road surface friction and other environmental load components in addition to load components which, even if small, are integral to system 100.

In accordance with the above-describe embodiments, a connector sealing interface between an enclosure and bottom mounted electrical connector for an electronic control unit may be achieved. In some embodiments, a sealing pedestal with a chamfer on an outer perimeter of the pedestal may be added between the enclosure and electrical connector sealing interface. The sealing pedestal with chamfer may reduce a gap formed between the enclosure and electrical connector when the enclosure is fastened to the electrical connector. Due to the reduced size of the gap, sealant bead thickness may be reduced and a more effective curing of sealant may be provided. Additionally, the sealing pedestal may reduce bending deformation during the fastening of the enclosure to the electrical connector.

Further written description of a number of example embodiments shall now be provided.

Example embodiment 1 is an apparatus comprising: electronic control unit including: a housing including a cover plate and an enclosure coupled with the cover plate, the enclosure including a connector opening and a fastener opening spaced apart from the connector opening; a printer circuit board (PCB) contained within the housing intermediate the cover plate and the enclosure; an electrical connector operatively coupled with the PCB and extending through the connector opening to an exterior of the housing and including a fastener receptacle; a fastener extending through the fastener opening and extending into and engaging the fastener receptacle to fasten the electrical connector to the enclosure; and a sealing interface formed between an interior surface of the enclosure and the electrical connector, the sealing interface including: a pedestal protruding from the interior surface of the enclosure; a receiving groove formed in the electrical connector and receiving at least a portion of the pedestal; and a sealant bead disposed intermediate and contacting the pedestal and the receiving groove to form a seal.

Example embodiment 2 includes the features of example embodiment 1, wherein the pedestal surrounds the connector opening of the enclosure that receives electrical connector.

Example embodiment 3 includes the features of example embodiment 1, wherein the fastener opening extends through a portion of the pedestal.

Example embodiment 4 includes the features of example embodiment 1, wherein a chamfer is provided on an outer perimeter of the pedestal.

Example embodiment 5 includes the features of example embodiment 4, wherein the chamfer is provided adjacent an abutting interface of the pedestal and the receiving groove.

Example embodiment 6 includes the features of example embodiment 1, wherein the enclosure includes a second fastener opening spaced apart from the fastener opening and the connector opening, the electrical connector includes a second fastener receptacle spaced apart from the fastener receptacle, and a second fastener extends through the second fastener opening and extends into and engages the second fastener receptacle to fasten the electrical connector to the enclosure.

Example embodiment 7 includes the features of example embodiment 6, wherein a portion of the pedestal includes the fastener opening and second fastener opening at the opposite sides of the connector opening.

Example embodiment 8 includes the features of example embodiment 1, wherein a gap is provided between an outer side surface of the pedestal and an outer side surface of the groove when the enclosure is fastened to the electrical connector.

Example embodiment 9 includes the features of example embodiment 8, wherein at least a portion of the sealant bead is positioned in the gap.

Example embodiment 10 includes the features of example embodiment 1, wherein the sealant bead is an adhesive.

Example embodiment 11 includes the features of example embodiment 4, wherein a portion of the sealant bead contacts the pedestal and the chamfer.

Example embodiment 12 is a process comprising: providing unassembled electronic control unit components comprising: a housing including a cover plate and an enclosure coupled with the cover plate, the enclosure including a connector opening and a fastener opening spaced apart from the connector opening; a printer circuit board (PCB) contained within the housing intermediate the cover plate and the enclosure; an electrical connector operatively coupled with the PCB and extending through the connector opening to an exterior of the housing and including a fastener receptacle; a fastener extending through the fastener opening and extending into and engaging the fastener receptacle to fasten the electrical connector to the enclosure; and a sealing interface formed between an interior surface of the enclosure and the electrical connector; and assembling the unassembled electronic control unit components, the assembling comprising: mounting the electrical connector onto the PCB; dispensing a sealant bead into a receiving groove formed in the electrical connector; inserting the electrical connector through the connector opening of the enclosure; receiving a pedestal protruding from the interior surface of the enclosure into the receiving groove; contacting the pedestal to the sealant bead in the receiving groove; and fastening the enclosure to the electrical connector, wherein the sealant bead is disposed intermediate and contacts the pedestal and the receiving groove to form a seal.

Example embodiment 13 includes the features of example embodiment 12, wherein the pedestal surrounds the connector opening of the enclosure the receives electrical connector.

Example embodiment 14 includes the features of example embodiment 12, wherein the fastener opening extends through a portion of the pedestal.

Example embodiment 15 includes the features of example embodiment 12, wherein a chamfer is provided on an outer perimeter of the pedestal.

Example embodiment 16 includes the features of example embodiment 15, wherein the chamfer is provided adjacent an abutting interface of the pedestal and the receiving groove.

Example embodiment 17 includes the features of example embodiment 12, wherein the enclosure includes a second fastener opening spaced apart from the fastener opening and the connector opening, the electrical connector includes a second fastener receptacle spaced apart from the fastener receptacle, and a second fastener extends through the second fastener opening and extends into and engages the second fastener receptacle to fasten the electrical connector to the enclosure.

Example embodiment 18 includes the features of example embodiment 17, wherein a portion of the pedestal includes the fastener opening and second fastener opening at the opposite sides of the connector opening.

Example embodiment 19 includes the features of example embodiment 12, wherein a gap is provided between an outer side surface of the pedestal and an outer side surface of the groove when the enclosure is fastened to the electrical connector.

Example embodiment 20 includes the features of example embodiment 19, wherein at least a portion of the sealant bead is dispensed into the gap.

Example embodiment 21 includes the features of example embodiment 12, wherein the sealant bead is an adhesive.

While example embodiments of the disclosure have been illustrated and described in detail in the drawings and foregoing description, the same is to be considered as illustrative and not restrictive in character, it being understood that only certain example embodiments have been shown and described and that all changes and modifications that come within the spirit of the claimed inventions are desired to be protected. It should be understood that while the use of words such as preferable, preferably, preferred or more preferred utilized in the description above indicates that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary.

What is claimed is:

1. An apparatus comprising:
electronic control unit including:
a housing including a cover plate and an enclosure coupled with the cover plate, the enclosure including a connector opening and a fastener opening spaced apart from the connector opening;
a printer circuit board (PCB) contained within the housing intermediate the cover plate and the enclosure;
an electrical connector operatively coupled with the PCB and extending through the connector opening to an exterior of the housing and including a fastener receptacle;
a fastener extending through the fastener opening and extending into and engaging the fastener receptacle to fasten the electrical connector to the enclosure; and
a sealing interface formed between an interior surface of the enclosure and the electrical connector, the sealing interface including:
a pedestal protruding from the interior surface of the enclosure;
a receiving groove formed in the electrical connector and receiving at least a portion of the pedestal; and
a sealant bead disposed intermediate and contacting the pedestal and the receiving groove to form a seal.

2. The apparatus of claim 1, wherein the pedestal surrounds the connector opening of the enclosure that receives electrical connector.

3. The apparatus of claim 1, wherein the fastener opening extends through a portion of the pedestal.

4. The apparatus of claim 1, wherein a chamfer is provided on an outer perimeter of the pedestal.

5. The apparatus of claim 4, wherein the chamfer is provided adjacent an abutting interface of the pedestal and the receiving groove.

6. The apparatus of claim 1, wherein the enclosure includes a second fastener opening spaced apart from the fastener opening and the connector opening, the electrical connector includes a second fastener receptacle spaced apart from the fastener receptacle, and a second fastener extends through the second fastener opening and extends into and engages the second fastener receptacle to fasten the electrical connector to the enclosure.

7. The apparatus of claim 6, wherein a portion of the pedestal includes the fastener opening and second fastener opening at the opposite sides of the connector opening.

8. The apparatus of claim 1, wherein a gap is provided between an outer side surface of the pedestal and an outer side surface of the groove when the enclosure is fastened to the electrical connector.

9. The apparatus of claim 8, wherein at least a portion of the sealant bead is positioned in the gap.

10. The apparatus of claim 1, wherein the sealant bead is an adhesive.

11. The apparatus of claim 4, wherein a portion of the sealant bead contacts the pedestal and the chamfer.

12. A process comprising:
providing unassembled electronic control unit components comprising:
a housing including a cover plate and an enclosure coupled with the cover plate, the enclosure including a connector opening and a fastener opening spaced apart from the connector opening;
a printer circuit board (PCB) contained within the housing intermediate the cover plate and the enclosure;
an electrical connector operatively coupled with the PCB and extending through the connector opening to an exterior of the housing and including a fastener receptacle;
a fastener extending through the fastener opening and extending into and engaging the fastener receptacle to fasten the electrical connector to the enclosure; and
a sealing interface formed between an interior surface of the enclosure and the electrical connector; and
assembling the unassembled electronic control unit components, the assembling comprising:
mounting the electrical connector onto the PCB;
dispensing a sealant bead into a receiving groove formed in the electrical connector;
inserting the electrical connector through the connector opening of the enclosure;
receiving a pedestal protruding from the interior surface of the enclosure into the receiving groove;
contacting the pedestal to the sealant bead in the receiving groove; and
fastening the enclosure to the electrical connector,
wherein the sealant bead is disposed intermediate and contacts the pedestal and the receiving groove to form a seal.

13. The process of claim 12, wherein the pedestal surrounds the connector opening of the enclosure the receives electrical connector.

14. The process of claim 12, wherein the fastener opening extends through a portion of the pedestal.

15. The process of claim 12, wherein a chamfer is provided on an outer perimeter of the pedestal.

16. The process of claim 15, wherein the chamfer is provided adjacent an abutting interface of the pedestal and the receiving groove.

17. The process of claim 12, wherein the enclosure includes a second fastener opening spaced apart from the fastener opening and the connector opening, the electrical connector includes a second fastener receptacle spaced apart from the fastener receptacle, and a second fastener extends through the second fastener opening and extends into and engages the second fastener receptacle to fasten the electrical connector to the enclosure.

18. The process of claim 17, wherein a portion of the pedestal includes the fastener opening and second fastener opening at the opposite sides of the connector opening.

19. The process of claim 12, wherein a gap is provided between an outer side surface of the pedestal and an outer side surface of the groove when the enclosure is fastened to the electrical connector.

20. The process of claim 19, wherein at least a portion of the sealant bead is dispensed into the gap.

21. The process of claim 12, wherein the sealant bead is an adhesive.

22. The process of claim 15, wherein a portion of the sealant bead contacts the pedestal and the chamfer.
